(19) United States
(12) Patent Application Publication
(10) Pub. No.: US 2014/0055143 A1
(43) Pub. Date: Feb. 27, 2014

(54) BATTERY TESTING SYSTEM WITH ENERGY CIRCULATION

(71) Applicants: Fa-Hwa Shieh, Longtan Township (TW); Ming-Lun Liu, Longtan Township (TW); You-Rong Lin, Longtan Township (TW); Wen-Chen Lih, Longtan Township (TW); Yu-Min Liao, Longtan Township (TW)

(72) Inventors: Fa-Hwa Shieh, Longtan Township (TW); Ming-Lun Liu, Longtan Township (TW); You-Rong Lin, Longtan Township (TW); Wen-Chen Lih, Longtan Township (TW); Yu-Min Liao, Longtan Township (TW)

(73) Assignee: CHUNG-SHAN INSTITUTE OF SCIENCE AND TECHNOLOGY, Longtan Township (TW)

(21) Appl. No.: 13/626,845

(22) Filed: Sep. 25, 2012

(30) Foreign Application Priority Data
Aug. 22, 2012 (TW) 101216107

(51) Int. Cl. G01R 31/36

(52) U.S. Cl. 324/426

(57) ABSTRACT

A battery testing system with energy circulation includes a battery module to be tested, an electric power storage module, a bi-directional conversion module and a control module, and the control module controls the bi-directional conversion module to discharge the electric power storage module and charge the battery module to be tested, or discharge the battery module to be tested and charge the electric power storage module, so that the electricity can be fully and repeatedly used, and the electric power storage module can use a second-used power battery to save the cost of the electric power storage module while the battery testing system can be isolated from the grid of utility power to avoid creating a burden to the grid of the utility power.

### FIELD OF THE INVENTION

The present invention relates to a battery testing system with energy circulation, in particular to the battery testing system used for calibrating the state of charge to achieve the effects of testing the state of charge of a battery by a second-used power battery, and improving the life of the second-used power battery.

### BACKGROUND OF THE INVENTION

For energy saving and carbon reduction, the power source of a car is developed with a hybrid or even a purely electric car design, wherein the electric car such as an electric bus, an electric car, an electric motorcycle and any other electric transportation means requires a power battery with a large capacity to substitute the power source of petrochemical fuels, so that the power battery will be mass produced and tested according to the market requirements. After being used for a while, the power battery will be aged and its full charge capacity (FCC) will drop. If the full charge capacity drops below a specific standard such as a drop to a level below 70%, such battery may fail to satisfy the power requirement and must be discarded. Now, although the full charge capacity (FCC) of the discarded power battery no longer can satisfy the power requirements of the electric car, it still has the function of storing power to a certain level, so that many discarded power battery are used for other power storage applications, and such power battery is called the second-used battery.

In general, the manufacturing process of a brand-new battery or battery module requires a procedure of calibrating the state of charge (SOC) which primarily includes the following steps: discharging the state of charge (SOC) of the battery or battery module to 0%; fully charging and discharging the battery, and then charging the state of charge (SOC) to 50%. Similarly, the aforementioned testing and calibrating procedures are required for the power battery being used as a second-used battery. In the discharge or fully discharge procedure of the battery or battery module, the discharged energy is converted into heat energy directly and wasted directly.

The conventional battery or battery module using a charger for the charge and discharge generally adopts a loader for the discharge. With reference to FIG. 1 for a schematic view of charging and discharging a conventional battery module, the battery module comprises a controller A1, a loader A2, a battery to be tested A3 and a charger A4, wherein the battery to be tested A3 discharges electric power to the loader A2, and the charger A4 charges the battery to be tested A3. During the discharge, all discharged energies are consumed by the loader and converted into heat energy, and thus giving rise to a serious waste of energy and an increase of ambient temperature which may affect the precision of calibrating the state of charge.

In view of the aforementioned drawbacks of charging and discharging the conventional battery module, the inventor of the present invention based on years of experience in the related industry to conduct extensive researches and experiments, and finally designed a battery testing system with energy circulation to overcome the drawbacks of the prior art.

### SUMMARY OF THE INVENTION

Therefore, it is a primary objective of the present invention to overcome the shortcomings of the prior art by providing a battery testing system with energy circulation and capable of extending the life of an electric power storage module, wherein the electric power storage module has a total electric power capacity equal to a multiple of the total electric power capacity of the battery module to be tested, so that the state of charge of the electric power storage module can be set to a neighborhood near 70% and 30% in order to charge the state of charge of the battery module to be tested to 100%, and if the battery module to be tested is discharged by a current of 1 C, the full charge capacity of the electric power storage module is charged by a current much smaller than 1 C. As to the electric power storage module, if the state of charge has not reached 100%-0%, and the charging current is much smaller than 1 C, the rise of the operating temperature is much smaller than that at the state of charge reaching 100%-0% and the charging current equal to 1 C. Therefore, the present invention can achieve the effect of providing an electric power storage module with a smaller temperature rise which can extend the service life of the electric power storage module.

A secondary objective of the present invention is to provide a battery testing system with energy circulation, and the battery testing system can use a second-used power battery as a battery installed in a power storage module in order to reduce the purchase cost and achieve the effects of fully utilizing a discarded power battery, avoiding unnecessary waste of resources, protecting environment, saving energy and reducing carbon.

It is a third objective of the present invention to provide a battery testing system with energy circulation, wherein the required energy can be supplied by an electric power storage module, and the electric energy discharged from the battery module to be tested is stored by the electric power storage module and prepared for the next discharge, so that the energy can be fully and repeatedly utilized, and can be isolated from the grid of utility power to avoid creating a burden to the grid of the utility power.

To achieve the foregoing objectives, the present invention to provide a battery testing system with energy circulation, comprising a battery module to be tested; an electric power storage module, having a total electric power capacity equal to a multiple of the total electric power capacity of the battery module to be tested; a first bi-directional conversion module, electrically coupled to the battery module to be tested and the electric power storage module; and a control module, electrically coupled to the battery module to be tested, the electric power storage module and the first bi-directional conversion module for monitoring a state of charge of the battery module to be tested and the electric power storage module, wherein the control module can control the first bi-directional conversion module to discharge the electric power storage module and charge the battery module to be tested. In addition, the control module can further control the first bi-directional conversion module to discharge the battery module to be tested and charge the electric power storage module, wherein the electric power storage module has a full charge capacity equal to a multiple of the full charge capacity (such as four times) of the battery module to be tested. When the current of 1 C of the battery module to be tested is used for a fully charge or discharge (or the state of charge of the battery module to be tested state of charge is changed from 0% to 100%, and then from 100% to 0%), the full charge capacity of electric power storage module is equal to four times of the full charge capacity of the battery module to be tested. For the electric power storage module, a current of 0.25 C is used for the charge and discharge, and the change of the full charge capacity of the electric power storage module is only 25%, which has a much smaller quantity of generated heat than the condition of using the current of 1 C for the discharge and charge and having a change of full charge capacity of the electric power storage module equal to 100%. The smaller quantity of the generated heat, the smaller is the temperature rise. The temperature rise will give rise to a high impedance inside the battery and shorten the life of the battery, so that the full charge capacity of the electric power storage module is designed to be a multiple of the full charge capacity of the battery module to be tested, and the electric power storage module can have a longer service life, wherein the first bi-directional conversion module is a DC/DC converter.

In the second preferred embodiment of the present invention, the battery testing system with energy circulation further comprises a second bi-directional conversion module coupled to utility AC power, wherein the second bi-directional conversion module is coupled to the control module and the electric power storage module, and when the battery module to be tested has insufficient state of charge to charge the electric power storage module and the electric power storage module has a state of charge below a predetermined lower limit such as 30%, the control module can control the second bi-directional conversion module to charge the electric power storage module by the utility AC power, wherein the state of charge of the electric power storage module is charged to a predetermined upper limit such as 70% first, and then the battery to be tested is tested, and the second bi-directional conversion module is an AC/DC converter.

In the third preferred embodiment of the present invention, the battery testing system with energy circulation further comprises an AC power measuring device coupled to an external AC power supply device and the second bi-directional conversion module, wherein the Ac power measuring device is operated by AC, and when the AC power measuring device is operated by the power supplied by the external AC power supply device, or the external AC power supply is disconnected, the control module will control the second bi-directional conversion module to supply electric power by the electric power storage module, wherein the second bi-directional conversion module is an AC/DC converter.

### BRIEF DESCRIPTION OF THE DRAWINGS

FIG. 1 is a schematic view of charging and discharging a conventional battery module;

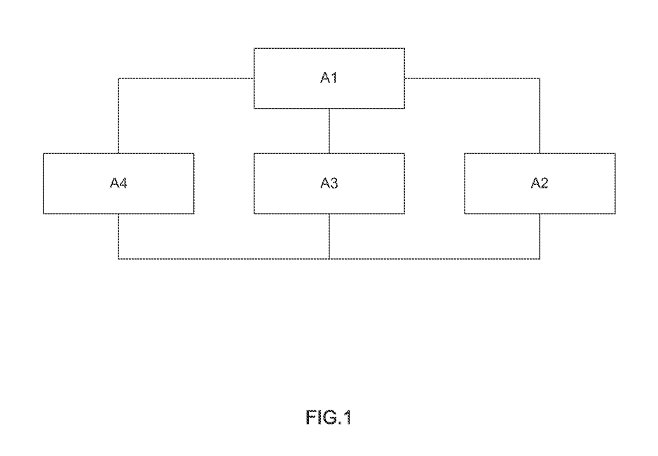

FIG. 2 is a schematic view of a first preferred embodiment of the present invention;

FIG. 3 is a schematic view of a second preferred embodiment of the present invention; and

FIG. 4 is a schematic view of a third preferred embodiment of the present invention.

### DESCRIPTION OF THE PREFERRED EMBODIMENTS

The technical characteristics of the present invention will become apparent with the detailed description of the preferred embodiments accompanied with the illustration of related drawings as follows. It is noteworthy that same numerals are used for representing the same respective elements in the drawings, and the drawings are provided for the purpose of illustrating the invention, but not intended for limiting the scope of the invention.

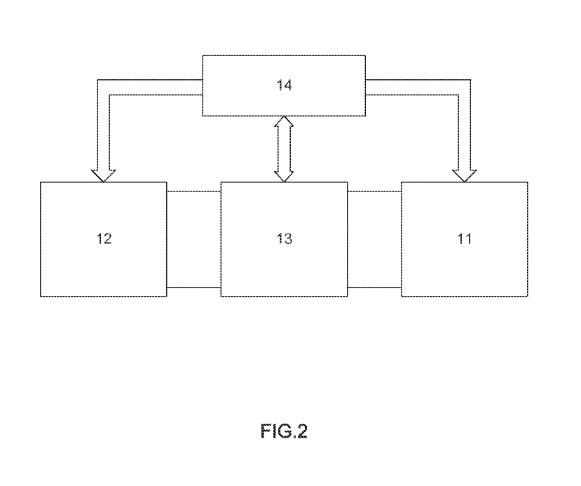

With reference to FIG. 2 for the major components of a battery testing system with energy circulation in accordance with a first preferred embodiment of the present invention, the battery testing system comprises a battery module to be tested 11; an electric power storage module 12, with a total electric power capacity equal to of a multiple of the total electric power capacity the battery module to be tested 11; a first bi-directional conversion module 13, electrically coupled to the battery module to be tested 11 and the electric power storage module 12; and a control module 14, electrically coupled to the battery module to be tested 11, the electric power storage module 12 and the first bi-directional conversion module 13, for monitoring and measuring state of charge (SOC) of the battery module to be tested 11 and the electric power storage module 12, wherein the control module 14 can control the first bi-directional conversion module 13 to discharge the electric power storage module 12 and charge the battery module to be tested 11. In addition, the control module 14 further controls the first bi-directional conversion module 13 to discharge the battery module to be tested 11 and charge the electric power storage module 12.

In FIG. 2, the first bi-directional conversion module 13 can be a DC/DC converter or a power regular for converting the current discharged by the battery module to be tested 11 into a DC power required by the electric power storage module 12, as well as converting the current discharged by the electric power storage module 12 into the AC power required by the battery module to be tested 11. In addition, the bi-directional conversion module 13 can prevent a drastic change of current occurred while switching the power of the battery module to be tested 11 and the electric power storage module 12, and the bi-directional conversion module 13 is coupled to the battery module to be tested 11 and the electric power storage module 12 through a high potential line and a low potential line respectively, wherein the high potential line is provided for coupling high potential terminals of the battery module to be tested 11 and the electric power storage module 12 respectively, and the low potential line is provided for coupling low potential terminals of the battery module to be tested 11 and the electric power storage module 12 respectively.

Both of the battery module to be tested 11 and the electric power storage module 12 include at least one rechargeable battery, and the battery module to be tested 11 and the electric power storage module 12 is a rechargeable battery module.

the control module 14 is a calculating device comprising a processor, a microcontroller (MCU), a digital signal processor (DSP), a programmable logic controller (PLC), a logic circuit, a microcomputer, or a computer, and the control module 14 is coupled to the battery module to be tested 11 and the electric power storage module 12 through a sensing control path for sensing the state of charge, temperature and voltage of the battery module to be tested 11 and the electric power storage module 12 and controlling the bi-directional conversion module 13 to switch charging and discharging the battery module to be tested 11 and the electric power storage module 12, wherein after the control module 14 detects and measures the data from the battery module to be tested 11 and the electric power storage module 12, a Coulomb method or a diffusion law method is used for estimating the state of charge of the battery module to be tested 11 and the electric power storage module 12. In addition, the control module 14 transmits a warning message or a failure message to a battery management center via a wireless or cable connection to allow a power manager to monitor the status of the battery module to be tested 11 and the electric power storage module 12.

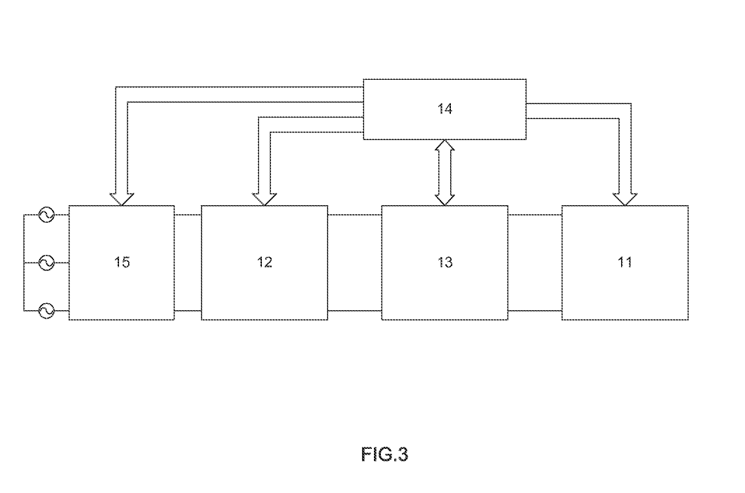

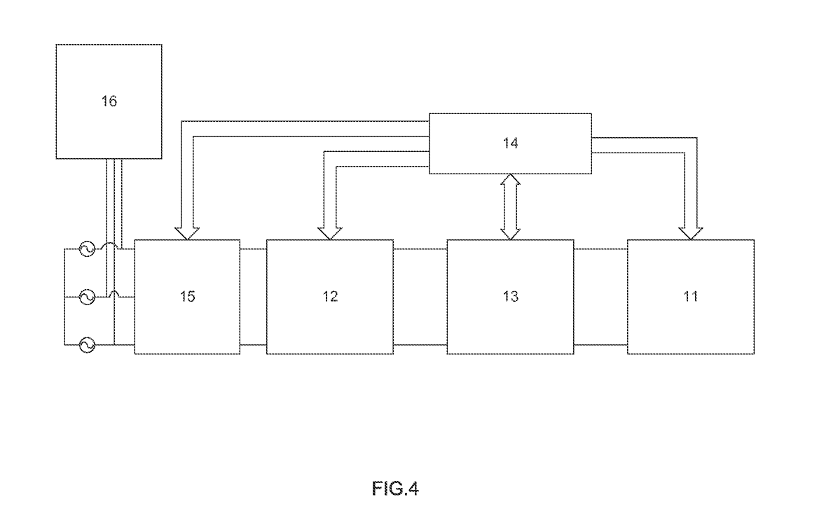

With reference to FIGS. 3 and 4 for schematic views of a battery testing system with energy circulation in accordance with the second and third preferred embodiments of the present invention respectively, the battery testing system further comprises a second bi-directional conversion module 15 coupled to an AC power source, and also coupled to the control module 14 and the electric power storage module 12, wherein when the battery module to be tested 11 no longer has sufficient state of charge to charge the electric power storage module 12, and the electric power storage module 12 has a state of charge below a predetermined lower limit such as 30%, the control module 14 can control the second bi-directional conversion module 15 to charge the electric power storage module 12 by utility AC power, the battery can be tested after the state of charge of the electric power storage module has been charged up to a predetermined upper limit such as 70%.

With reference to FIGS. 3 and 4, the second bi-directional conversion module 15 is an AC/DC converter coupled to utility AC power for converting the AC power outputted from the utility AC power into DC power and then transmitted to the electric power storage module 12 as shown in FIG. 3, and the second bi-directional conversion module 15 is coupled to an external AC power measuring device 16 such as an oscilloscope or a recorder as shown in FIG. 4, and when the utility AC power is disconnected, the control module 14 controls the second bi-directional conversion module 15 to convert the electric energy in the electric power storage module 12 into AC to carry out the measuring function of the external AC power measuring device 16.

To make the battery testing system with energy circulation of the present invention more efficient, and extend the service life of the electric power storage module 12, guidelines are given as follows:

(1) Since the electric power storage module 12 has a total electric power capacity equal to a multiple (such as four times) of that of the battery module to be tested 11, therefore the state of charge of the electric power storage module 12 is set with upper and lower limits equal to 70% and 30% respectively. If the state of charge exceeds the upper and lower limits, the control module 14 will issue a warning message, wherein if the state of charge is less than the lower limit, the electric power storage module 12 will charge the electric power storage module 12 with the utility power through the second bi-directional conversion module 15 controlled by the control module 14, the state of charge of the electric power storage module is charged to a predetermined upper limit such as 70%, and then the battery is tested. If the state of charge exceeds the upper limit, the electric power storage module 12 can supply power to the external AC power measuring device 16 through the second bi-directional conversion module 15 to reduce the state of charge, and the upper and lower limits are set to 70% and 30% respectively in order to control the operating interval of the state of charge of the electric power storage module 12. After extensive researches and experiments, the inventor of the present invention discovers that the state of charge set to 70% and 30% can have a smaller temperature change, such that he electric power storage module 12 can have a longer service life.

(2) Taking safety into consideration, the present invention can set limits to the state of charge of the battery module to be tested 11. For example, if the state of charge of the battery module to be tested 11 is equal to 98%, the control module 14 will send out a warning message to protect the battery module to be tested 11 and will stop charging at an appropriate time; and if the state of charge of the battery module to be tested 11 is equal to 2%, the control module 14 will send out a warning message to protect the battery module to be tested 11 and will stop discharging at an appropriate time, wherein 98% and 2% are just adopted in a preferred embodiment of the present invention, and they can be adjusted according to the actual operation requirements.

In summation of the description above, the battery testing system with energy circulation of the present invention has the following advantages:

(1) The electric power storage module has a total electric power capacity equal to a multiple of that of the battery module to be tested, so that the state of charge of the electric power storage module is set within a range between 70% and 30% to maintain the capability of charging the state of charge of the battery module to be tested to 100%. Compared with the conventional battery module with a state of charge falling between 0% and 100%, the present invention can achieve a lower temperature rise that can extend the life of the electric power storage module.

(2) A second-used power battery can be used as a charging battery of the electric power storage module, and the quantity of charging battery in the electric power storage module can be adjusted according to the total electric power capacity of the battery module to be tested, so that the total electric power capacity of the electric power storage module can be a multiple of the battery module to be tested, so that using the second-used power battery can reduce the purchase cost of buying a new battery module, and the original discarded battery used as the electric power storage module can maximize utility and avoid unnecessary waste of resources.

(3) In the present invention, the energy required for the whole testing system is supplied by the electric power storage module, and the electric energy discharged from the battery module to be tested is also stored by the electric power storage module for the next charge, so that energy can be fully and repeatedly utilized to achieve the energy-saving and carbon-reduction effects. In addition to the function of charging the state of charge of the electric power storage module whenever the state of charge falls below 30%, the present invention is isolated from the grid of utility power most of the time, so that the invention can avoid creating a burden to the grid of the utility power.

What is claimed is:

1. A battery testing system with energy circulation, comprising:
a battery module to be tested;
an electric power storage module, having a total electric power capacity equal to a multiple of the total electric power capacity of the battery module to be tested;
a first bi-directional conversion module, electrically coupled to the battery module to be tested and the electric power storage module; and
a control module, electrically coupled to the battery module to be tested,
thereby, the electric power storage module and the first bi-directional conversion module monitor a state of charge of the battery module to be tested and the electric power storage module, wherein the control module controls the first bi-directional conversion module to discharge the electric power storage module and charge the battery module to be tested; and
the control module further controls the first bi-directional conversion module to discharge the battery module to be tested and charge the electric power storage module.

2. The battery testing system with energy circulation according to claim 1, wherein the first bi-directional conversion module is a DC/DC converter.

3. The battery testing system with energy circulation according to claim 1, further comprising a second bi-directional conversion module of an AC power source, and the second bi-directional conversion module being coupled to the control module and the electric power storage module, wherein when the battery module to be tested has an insufficient state of charge, the battery module charges the electric power storage module, and if the state of charge of electric power storage module is below 30%, the control module controls the second bi-directional conversion module to convert the AC power source into AC used to charge the electric power storage module.

4. The battery testing system with energy circulation according to claim 1, further comprising a second bi-directional conversion module coupled to an AC power source, and the second bi-directional conversion module being coupled to the control module and the electric power storage module, wherein when the battery module to be tested still has sufficient state of charge to charge the electric power storage module, and the state of charge of the electric power storage module reaches 70%, the control module controls the second bi-directional conversion module to supply electric power to an external AC power measuring device to reduce the state of charge.

5. The battery testing system with energy circulation according to claim 3, wherein the second bi-directional conversion module is an AC/DC converter.

6. The battery testing system with energy circulation according to claim 3, wherein the AC power source is a utility AC power.

7. The battery testing system with energy circulation according to claim 3, wherein the AC power measuring device is a device requiring alternate current for an operation in a battery testing system.
